(19) United States
(12) Patent Application Publication
(10) Pub. No.: US 2025/0201330 A1
(43) Pub. Date: Jun. 19, 2025

(54) SEMICONDUCTOR DEVICE AND OPERATING METHOD THEREOF

(71) Applicant: SK hynix Inc., Icheon-si (KR)

(72) Inventor: Jeong Hwan SONG, Icheon-si (KR)

(21) Appl. No.: 18/910,350

(22) Filed: Oct. 9, 2024

(30) Foreign Application Priority Data
Dec. 15, 2023 (KR) 10-2023-0183513

(51) Int. Cl. G11C 29/44; G11C 29/12; H10B 61/00; H10B 63/00; H10B 63/10

(52) U.S. Cl. CPC G11C 29/44; G11C 29/12005; H10B 61/00; H10B 63/10; H10B 63/24

(57) ABSTRACT

A semiconductor device is provided to include first conductive lines extending in a first direction; a second conductive lines disposed to be spaced apart from the first conductive lines in a third direction and extending in a second direction intersecting with the first direction; a memory cells overlapping with intersection areas of the first conductive lines and the second conductive lines; and first variable resistance patterns that are respectively coupled in series to the memory cells, one first variable resistance pattern per memory cell, so that each first variable resistance pattern and a corresponding memory cell are connected between a corresponding first conductive line of the first conductive lines and a corresponding second conductive line of the second conductive lines.

### PRIORITY CLAIM AND CROSS-REFERENCE TO RELATED APPLICATIONS

This patent document claims priority under 35 U.S.C. 119 (a) to Korean Patent Application No. 10-2023-0183513, filed on Dec. 15, 2023, in the Korean Intellectual Property Office, which is incorporated herein by reference in its entirety.

### TECHNICAL FIELD

Exemplary embodiments of the present disclosure relate to a semiconductor technology, and more particularly, to a semiconductor device including a variable resistance pattern, and a method for operating the semiconductor device.

### BACKGROUND

Recent trends for miniaturization, low-power consumption, high performance, and diversification of electronic devices require semiconductor devices that may store data in diverse electronic devices, such as computers and portable communication devices, and researchers and the industry are studying to develop such semiconductor devices. Such semiconductor devices are capable of storing data by using the characteristic of switching between different resistance states according to the applied voltage or current. The examples of such semiconductor devices include a Resistive Random Access Memory (RRAM), a Phase-change Random Access Memory (PRAM), a Ferroelectric Random Access Memory (FRAM), a Magnetic Random Access Memory (MRAM), an E-fuse, and the like.

### SUMMARY

Embodiments of the present disclosure are directed to a semiconductor device that may improve operation characteristics by preventing defects, such as leakage current, and a method for operating the semiconductor device.

In accordance with an embodiment of the present disclosure, a semiconductor device includes: a plurality of first conductive lines extending in a first direction; a plurality of second conductive lines disposed to be spaced apart from the plurality of first conductive lines in a third direction and extending in a second direction intersecting with the first direction; a plurality of memory cells overlapping with intersection areas of the plurality of first conductive lines and the plurality of second conductive lines; and a plurality of first variable resistance patterns that are respectively coupled in series to the plurality of memory cells, one first variable resistance pattern per memory cell, so that each first variable resistance pattern and a corresponding memory cell are connected between a corresponding first conductive line of the plurality of first conductive lines and a corresponding second conductive line of the plurality of second conductive lines.

In accordance with another embodiment of the present disclosure, a method for operating a semiconductor device is provided, wherein the semiconductor device includes a plurality of first conductive lines extending in a first direction; a plurality of second conductive lines disposed to be spaced apart from the plurality of first conductive lines in a third direction and extending in a second direction intersecting with the first direction; a plurality of memory cells overlapping with intersection areas of the plurality of first conductive lines and the plurality of second conductive lines; and a plurality of first variable resistance patterns formed to be connected in series with the plurality of memory cells, respectively, one first variable resistance pattern per memory cell, so that each first variable resistance pattern and a corresponding memory cell are connected between a corresponding first conductive line of the plurality of first conductive lines and a corresponding second conductive line of the plurality of second conductive lines. The method comprises: determining whether or not a defective memory cell with a short failure exists among the plurality of memory cells; and in response to the determining that the defective memory cell exists, performing a reset operation to allow a first variable resistance pattern that is coupled to the defective memory cell to exhibit a high resistance state to block an electrical connection to the defective memory cell.

The above and other aspects of the disclosed technology are disclosed in the drawings, the detailed description and the claims.

### BRIEF DESCRIPTION OF THE DRAWINGS

FIG. 1A is a perspective view illustrating an example of a semiconductor device in accordance with an embodiment of the present disclosure.

FIG. 1B is a cross-sectional view illustrating an example of a memory cell 120 shown in FIG. 1A.

FIG. 1C is a cross-sectional view illustrating another example of the memory cell 120 shown in FIG. 1A.

FIG. 1D is a cross-sectional view illustrating an example of a second variable resistance pattern 127 shown in FIG. 1B.

FIGS. 2A to 2C are examples of cross-sectional views illustrating diverse states of the semiconductor device shown in FIG. 1A.

FIG. 3 is an example of a flowchart describing a method for operating a semiconductor device in accordance with an embodiment of the present disclosure.

### DETAILED DESCRIPTION

Exemplary embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

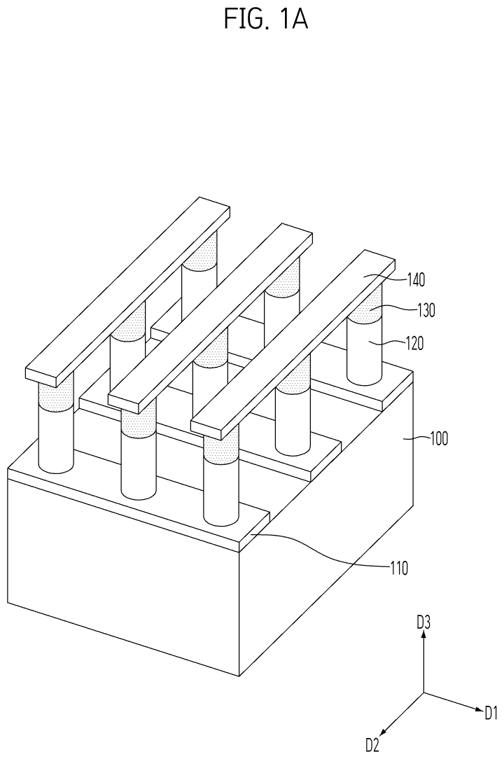

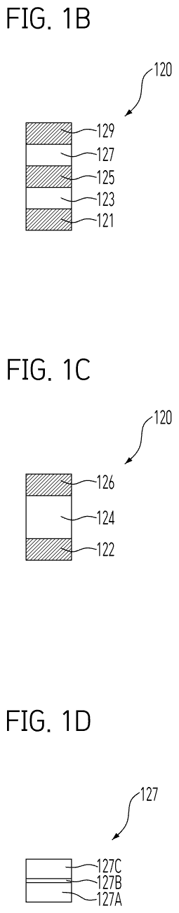

FIG. 1A is a perspective view illustrating an example of a semiconductor device in accordance with an embodiment of the present disclosure.

Referring to FIG. 1A, the semiconductor device in accordance with this embodiment of the present disclosure may include a plurality of first conductive lines 110 formed over a substrate 100 and extending in a first direction D1, a plurality of second conductive lines 140 formed to be spaced apart from the first conductive lines 110 in a third direction D3 and extending in a second direction D2 intersecting with the first direction D1, a plurality of memory cells 120 respectively overlapping with the intersection areas of the first conductive lines 110 and the second conductive lines 140 between the first conductive lines 110 and the second conductive lines 140, and a first variable resistance pattern 130 interposed between each of the memory cells 120 and each of the second conductive line 140. Here, the first direction D1 and the second direction D2 may correspond to horizontal directions that are substantially parallel to the top surface of the substrate 100. For example, the first direction D1 and the second direction D2 may be perpendicular to each other in a same plane. The third direction D3 may correspond to a vertical direction that is substantially perpendicular to the top surface of the substrate 100. However, the present disclosure is not limited to this, and the first to third directions D1-D3 may be modified in various manners on the premise that they intersect with one another. For example, unlike what is illustrated, the first direction D1 and the second direction D2 may correspond to the vertical directions, and the third direction D3 may correspond to the horizontal direction.

The substrate 100 may include a semiconductor material, such as silicon. A required predetermined lower structure (not shown) may be formed in the substrate 100. For example, the substrate 100 may be electrically connected to the first conductive lines 110 and/or the second conductive lines 140 and may include a driving circuit (not shown) for controlling the first conductive lines 110 and/or the second conductive lines 140.

A first conductive line 110 and a second conductive line 140 may be electrically coupled to the lower and upper ends of each memory cell 120, respectively, and transfer operation voltage and/or operation current to the memory cell 120 to operate the memory cell 120. In the illustrated example in FIG. 1A, memory cells 120 are located below the second conductive lines 140 and above the first conductive lines 110 and are coupled to the first conductive lines 110 and second conductive lines 140. When the first conductive lines 110 function as word lines, the second conductive lines 140 may function as bit lines. Conversely, when the first conductive lines 110 function as bit lines, the second conductive lines 140 may function as word lines. Each of the first conductive lines 110 and the second conductive lines 140 may include diverse conductive materials, for example, metals such as platinum (Pt), tungsten (W), aluminum (Al), copper (Cu), tantalum (Ta) or others, metal nitrides such as titanium nitride (TiN), tantalum nitride (TaN) or others, or combinations thereof, and may have a single-layer structure or a multi-layer structure.

A memory cell 120 may store data. The memory cell 120 may be configured to store data based on various schemes for storing data.

For example, the memory cell 120 may store two different data by switching between different resistance states according to the voltage or current that is applied through the first conductive line 110 and the second conductive line 140. In some implementations, the memory cell 120 may store more than two different data by controlling the voltage or current applied to the memory cell 120. The storing of data in the memory cell 120 will be described below with reference to FIGS. 1B to 1D.

FIG. 1B is a cross-sectional view illustrating an example of a memory cell 120 shown in FIG. 1A.

Referring to FIG. 1B, the memory cell 120 may include a stacked structure of a first electrode 121, a selector pattern 123, a second electrode 125, a second variable resistance pattern 127, and a third electrode 129.

The first electrode 121 may be interposed between the first conductive line 110 and the selector pattern 123 and may function to electrically connect them to each other while physically separating them from each other. The second electrode 125 may be interposed between the selector pattern 123 and the variable resistance pattern 127 and may function to electrically connect them to each other while physically separating them from each other. The third electrode 129 may be interposed between the variable resistance pattern 127 and the second conductive line 140 and may function to electrically connect them to each other while physically separating them from each other. Each of the first electrode 121, the second electrode 125, and the third electrode 129 may include diverse conductive materials, for example, metals such as platinum (Pt), tungsten (W), aluminum (Al), copper (Cu), tantalum (Ta) or others, metal nitrides such as titanium nitride (TiN), tantalum nitride (TaN) or others, or combinations thereof. In some implementations, at least one of the first electrode 121, the second electrode 125, and the third electrode 129 may include a carbon electrode.

The selector pattern 123 may function to control the access to the memory cell 120 and prevent leakage current that may occur between the memory cells 120 that share the first conductive line 110 or the second conductive line 140. In the implementations, the selector pattern 123 may have a threshold switching characteristic to selectively switch between two electrical conducting states: (1) an electrical non-conducting state that blocks a current to flow through or allows almost no current to flow through, when the applied voltage is smaller than a predetermined threshold, and (2) an electrical conducting state that allows a current to rapidly increase and flow through, when the applied voltage is equal to or greater than the predetermined threshold. This threshold may be called a threshold voltage or a threshold current, and the selector pattern 123 may be in a turn-on or turn-off state based on the threshold voltage or threshold current.

For example, the selector pattern 123 may include an OTS (Ovonic Threshold Switching) material such as a diode or a chalcogenide-based material, an MIEC (Mixed Ionic Electronic Conducting) material such as a metal-containing chalcogenide-based material, an MIT (Metal Insulator Transition) material such as NbO₂ or VO₂, a tunneling dielectric layer having a relatively wide band gap such as SiO₂, Al₂O₃, or others.

In some implementations, the selector pattern 123 may include a dielectric material that is doped with a dopant. The dielectric material may include a dielectric material having a relatively wide band gap, for example, a dielectric material having a band gap of approximately 5.0 eV or more. For example, the dielectric material may include a silicon-containing dielectric material such as silicon oxide, silicon nitride, silicon oxynitride, or others, a dielectric metal oxide, a dielectric metal nitride, or a combination thereof. In the selector pattern 123, there may be a deep trap whose energy level is closer to the energy level of the valence band than to the energy level of the conduction band of the dielectric material in the dielectric material. The dopant may serve to create a shallow trap that provides a path for the migration of conductive carriers, such as electrons or holes, in the dielectric material. The shallow trap may have an energy level that is closer to the energy level of the conduction band than to the energy level of the balance band of the dielectric material. For example, when the dielectric material contains silicon, the dopant may include a metal whose valence is different from that of silicon, such as gallium (Ga), boron (B), indium (In), phosphorus (P), arsenic (As), antimony (Sb), germanium (Ge), carbon (C), tungsten (W), or a combination thereof. When the dielectric material contains a metal, the dopant may include a metal whose valence is different from that of the metal, silicon, or others. For example, the selector pattern 123 may include silicon dioxide (SiO₂) that is doped with arsenic (As). In a turn-off state where no voltage or voltage less than the predetermined threshold is applied to the selector pattern 123, conductive carriers, such as electrons, may be trapped in the deep trap of the selector pattern 123. By applying a voltage equal to or greater than the threshold voltage to the selector pattern 123 which is in the turn-off state, it is possible to operate the selector pattern 120 to be in a turn-on state in which current flows through the selector pattern 123. When a voltage equal to or greater than the threshold voltage is applied to the selector pattern 123, the conductive carriers trapped in the deep trap may jump to the shallow trap by thermal emission or tunneling. As the conductive carriers migrate through the shallow trap, a current flow coupling the first electrode 121 and the second electrode 125 may be formed. When the voltage applied to the selector pattern 123 which is in the turn-on state is decreased, the number of the conductive carriers migrating from the deep trap to the shallow trap is decreased, and the selector pattern 123 may be turned off again.

Therefore, in the example in FIG. 1B, each memory cell 120 has an internal memory cell access control circuit which is the selector pattern 123 and an external memory cell access control circuit which is the first variable resistance pattern 130 which is connected in series to, and is located outside of, the memory cell 120. The internal memory cell access control circuit (selector pattern 123) and the external memory cell access control circuit (the first variable resistance pattern 130) are operated to control the electrical connection of the memory cell 120 to the corresponding first and second conductive lines for the memory cell 120.

The second variable resistance pattern 127 may be a part of the memory cell 120 that functions to store data. In this implementation, the second variable resistance pattern 127 may have variable resistance characteristics of switching between different resistance states for storing data and data writing operations according to the applied voltage. The second variable resistance pattern 127 may have a single-layer structure or a multi-layer structure containing diverse materials used in an RRAM, a PRAM, an FRAM, an MRAM, or others, for example, metal oxides such as transition metal oxides, perovskite-based materials, or others, phase change materials such as chalcogenide-based materials, or others, ferroelectric materials, ferromagnetic materials, or others.

However, the layer structure of the memory cell 120 is not limited to what has been illustrated above but may be modified diversely. For example, at least one among the first electrode 121, the selector pattern 123, the second electrode 125, and the third electrode 129 may be omitted. In some implementations, the memory cell 120 may further include one or more layers (not shown) that may improve the characteristics of the memory cell 120 in addition to the above-described layers 121 to 129. In some implementations, the positions of the selector pattern 123 and the second variable resistance pattern 127 may be switched.

FIG. 1C is a cross-sectional view illustrating another example of the memory cell 120 shown in FIG. 1A.

Referring to FIG. 1C, the memory cell 120 may include a stacked structure of a first electrode 122, a self-selecting memory pattern 124, and a third electrode 126.

The self-selecting memory pattern 124 may operate as a memory element and a selection element. In some implementations, the self-selecting memory pattern 124 may have a variable resistance characteristic exhibiting different resistance states or values to operate as the memory element for storing different data using the different resistance states of the self-selecting memory pattern 124 according to the voltage or current applied through the first electrode 122 and the second electrode 126, as well as a threshold switching characteristic to turn off the self-selecting memory pattern 124 to be electrically nonconductive and thus block or hold the current to scarcely flow through the self-selecting memory pattern 124 when the voltage applied through the first electrode 122 and the second electrode 126 is smaller than the threshold voltage, or turn on the self-selecting memory pattern 124 to be electrically conductive and thus allow the current to flow drastically through the self-selecting memory pattern 124 when the applied voltage is equal to or greater than the threshold voltage. In some implementations, the threshold voltage of the memory cell 120 may depend on the resistance state of the memory cell 120. In other words, the memory cell 120 may have different threshold voltages according to different resistance states. For example, when the memory cell 120 is in a first resistance state, it may have a first threshold voltage, and when the memory cell 120 is in a second resistance state which is different from the first resistance state, it may have a second threshold voltage which is different from the first threshold voltage. As a result, the memory cell 120 may be implemented as a self-selecting memory element that operates a memory element and a selection element.

FIG. 1D is a cross-sectional view illustrating an example of the

second variable resistance pattern 127 shown in FIG. 1B.

Referring to FIG. 1D, the second variable resistance pattern 127 may be a magnetic tunnel junction structure, and it may include a fixed layer 127A, a tunnel barrier layer 127B, and a free layer 127C.

The fixed layer 127A may be a layer having a fixed magnetization direction that may be compared with the magnetization direction of the free layer 127C, and the fixed layer 127A may also be called a reference layer. The free layer 127C may be a layer that may store different data by having a changeable magnetization direction, and the free layer 127C may also be called a storage layer. The tunnel barrier layer 127B may physically separate the fixed layer 127A and the free layer 127C from each other and enable tunneling of carriers, e.g., electrons, between the fixed layer 127A and the free layer 127C. Each of the fixed layer 127A and the free layer 127C may have a single-layer structure or a multi-layer structure including a ferromagnetic material.

For example, each of the fixed layer 127A and the free layer 127C may include an alloy containing Fe, Ni, or Co as a main component, for example, each of the fixed layer 127A and the free layer 127C may include at least one of Fe—Pt alloy, Fe—Pd alloy, Co—Pd alloy, Co—Pt alloy, Fe—Ni—Pt alloy, Co—Fe—Pt alloy, Co—Ni—Pt alloy, Fe—Pd alloy, or Co—Fe—B alloy, or at least one of a stacked structure of Co/Pt or a stacked structure of Co/Pd. The tunnel barrier layer 127B may have a single-layer structure or a multi-layer structure including a dielectric material. For example, the tunnel barrier layer 127B may include a dielectric oxide, such as MgO, CaO, SrO, TiO, VO, or NbO.

In this magnetic tunnel junction structure, the magnetization direction of the free layer 127C may vary according to the applied voltage or current. When the magnetization direction of the free layer 127C is parallel to the magnetization direction of the fixed layer 127A, the magnetic tunnel junction structure may have a low resistance state and may store, for example, data ‘1’. On the other hand, when the magnetization direction of the free layer 127C is anti-parallel to the magnetization direction of the fixed layer 127A, the magnetic tunnel junction structure may have a high resistance state and may store, for example, data ‘0’. In some other implementations, the magnetic tunnel junction structure may store data ‘1’ when magnetic tunnel junction structure has a high resistance state and the magnetic tunnel junction structure may store data ‘0’ when the magnetic tunnel junction structure has a low resistance state.

As long as the magnetic tunnel junction structure includes the fixed layer 127A, the free layer 127C, and the tunnel barrier layer 127B between the fixed layer 127A and the free layer 127C, the layer structure of the magnetic tunnel junction structure may be modified diversely. For example, the positions of the fixed layer 127A and the free layer 127C may be switched. In some implementations, the magnetic tunnel junction structure may further include one or more layers (although not shown) to improve the characteristics of the magnetic tunnel junction structure.

Referring back to FIG. 1A, the memory cell 120 may have a pillar shape that overlaps with the intersection area of the first conductive line 110 and the second conductive line 140. In the figure, the memory cell 120 is illustrated as having a cylindrical shape, but the present disclosure is not limited to this, and the memory cell 120 may have diverse shapes, such as a square pillar, an elliptical pillar, or others. In this figure, a plurality of layers forming the memory cell 120, for example, the layers 121 to 129 of FIG. 1B, are illustrated as having sidewalls that are aligned with each other by being patterned using a mask. However, the present disclosure is not limited to this. In particular, when the second variable resistance pattern 127 has a multi-layer structure such as a magnetic tunnel junction structure, it may be difficult to etch all the layers forming the memory cell 120 at once. In this case, the layers forming the memory cell 120 may be divided into two or more parts and patterned separately. For example, the selector pattern 123 and the second variable resistance pattern 127 of FIG. 1B may be patterned separately using different masks and as a result, they may have sidewalls that are not aligned with each other.

In the semiconductor device, diverse operations may be performed, which include a program operation of storing data in one or more memory cells 120 that are selected among the memory cells 120, a read operation of reading the data stored in one or more memory cells 120 that are selected among the memory cells 120, or others. The voltage or current applied through the first conductive line 110 and the second conductive line 140 for diverse operations, such as a program operation and a read operation, may be hereinafter referred to as an operation voltage or operation current.

In some implementations, some of the memory cells 120 may correspond to defective memory cells that do not operate normally. A defective memory cell may interfere with the operation of a semiconductor device in several ways. For example, during the operation of a semiconductor device, when an excessive amount of current that is called overshooting current or spike current flows unintentionally through the memory cell 120, it may cause a short failure of the memory cell 120. Since the memory cell 120 with a short failure causes the supplied current to flow therethrough, the leakage current of the entire semiconductor device may be increased, which results in interrupting the operation of a normal memory cell. This is because as the leakage current is increased, more current is required for the operation of the normal memory cell.

According to this embodiment of the present disclosure, even though there is a defective memory cell, it is possible to prevent the undesirable effects due to the defective memory cell, such as an increase in the leakage current of the semiconductor device, by blocking and/or decreasing the current flow through the defective memory cell. The implementations of the present disclosure are suggested to include a first variable resistance pattern 130 interposed between each memory cell 120 and each second conductive line 140.

The first variable resistance pattern 130 may have variable resistance characteristics of switching between different resistance states according to an applied voltage or current to that first variable resistance pattern 130. For example, the first variable resistance pattern 130 may switch between a low resistance state for providing an electrical connection via the first variable resistance pattern 130 to the memory cell 120 and a high resistance state for blocking the electrical connection via the first variable resistance pattern 130 to the memory cell 120. In the description below, the operation of changing the resistance state of the first variable resistance pattern 130 from a high resistance state to a low resistance state may be referred to as a set operation, and the voltage or current required for the first variable resistance pattern 130 for the set operation may be referred to as a set voltage or a set current. In the description below, the operation of changing the resistance state of the first variable resistance pattern 130 from a low resistance state to a high resistance state may be referred to as a reset operation, and the voltage or current required for the first variable resistance pattern 130 for the reset operation may be referred to as a reset voltage or a reset current. The first variable resistance pattern 130 may have a single-layer structure or a multi-layer structure including diverse materials used in an RRAM, a PRAM, an FRAM, an MRAM, or others. The example materials used in the first variable resistance pattern 130 may include, for example, metal oxides such as transition metal oxides, perovskite-based materials, or others, phase change materials such as chalcogenide-based materials or others, or ferroelectric materials, ferromagnetic materials, or others.

In the implementations, the magnitude of the set voltage or set current and the magnitude of the reset voltage or reset current of the first variable resistance pattern 130 may be greater than the magnitude of the operation voltage or operation current of the memory cell 120. This may be to prevent the resistance state of the first variable resistance pattern 130 from being changed during the operation of the memory cell. Thus, a set/reset operation may be prevented from being performed during the operation of the memory cell 120, which will be described later. Accordingly, when the memory cell 120 includes the second variable resistance pattern 127 as illustrated in FIG. 1B or the self-selecting memory pattern 124 as illustrated in FIG. 1C, the magnitude of the set/reset voltage or set/reset current of the first variable resistance pattern 130 may be greater than the magnitude of the set/reset voltage or set/reset current required during a set/reset operation in which the resistance state of the second variable resistance pattern 127 or the self-selecting memory pattern 124 is changed. This is because the set/reset voltage or set/reset current of the second variable resistance pattern 127 or the self-selecting memory pattern 124 corresponds to a portion of the operation voltage or operation current. Since the set/reset voltage or set/reset current of the first variable resistance pattern 130 is different from the set/reset voltage or set/reset current of the second variable resistance pattern 127, the first variable resistance pattern 130 and the second variable resistance pattern 127 may have different materials or layer structures from each other. For example, the first variable resistance pattern 130 may include a phase change material, and the second variable resistance pattern 127 may include the magnetic tunnel junction structure described in FIG. 1D. When the first variable resistance pattern 130 includes a phase change material, a low-resistance first variable resistance pattern 130 may have a crystalline state and a high-resistance first variable resistance pattern 130 may have an amorphous state. A case where an amorphous phase change material changes into a crystalline phase change material may correspond to a set operation, and a case where a crystalline phase change material changes into an amorphous phase change material may correspond to a reset operation.

The first variable resistance pattern 130 may have a pillar shape that overlaps with each of the memory cells 120. For example, the first variable resistance pattern 130 may be patterned together with the memory cell 120 to have a cylindrical shape with its sidewalls aligned with the memory cell 120. However, the present disclosure is not limited to this, and as long as the first variable resistance pattern 130 has a pillar shape that overlaps with each of the memory cells 120, the sidewall of the first variable resistance pattern 130 may not have to be aligned with the sidewall of the memory cell 120, and the shape of the first variable resistance pattern 130 may also be modified diversely. In this embodiment of the present disclosure, the first variable resistance pattern 130 is illustrated to be interposed between the second conductive line 140 and the memory cell 120, but the present disclosure is not limited thereto. For another example, the first variable resistance pattern 130 may be interposed between the first conductive line 110 and the memory cell 120. Also, for another example, the first variable resistance pattern 130 may be interposed between the first conductive line 110 and the memory cell 120 and between the second conductive line 140 and the memory cell 120.

When the first variable resistance pattern 130 has a low resistance state, for example, when the first variable resistance pattern 130 includes a crystalline phase change material, it may be said that the memory cell 120 and the second conductive line 140 are electrically connected through the first variable resistance pattern 130. This is because the first variable resistance pattern 130 is in a low resistance state, so the current flows smoothly between the memory cell 120 and the second conductive line 140. On the other hand, when the first variable resistance pattern 130 has a high resistance state, for example, when the first variable resistance pattern 130 includes an amorphous phase change material, it may be said that the memory cell 120 and the second conductive line 140 are electrically blocked by the first variable resistance pattern 130. This is because the first variable resistance pattern 130 is in a high resistance state, and thus the current flow between the memory cell 120 and the second conductive line 140 is greatly decreased or substantially blocked.

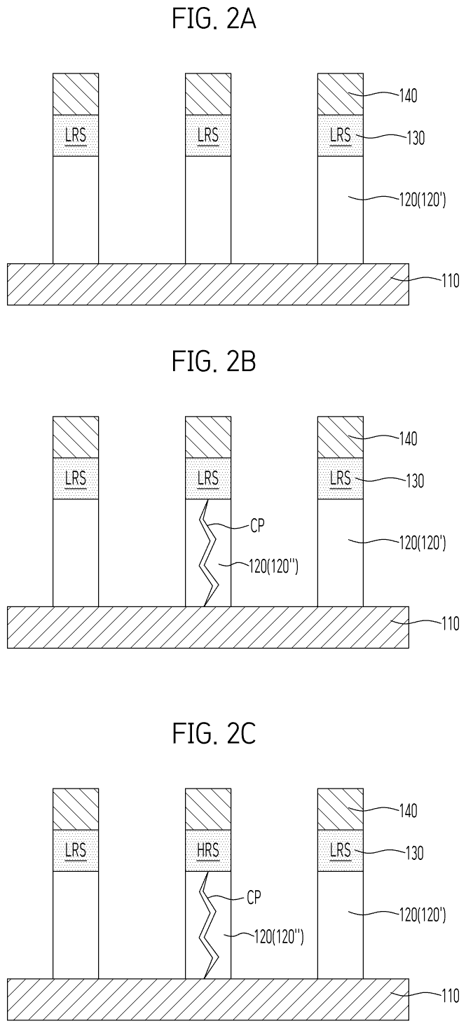

The semiconductor device may normally perform the operation of a normal memory cell without an interruption while blocking and/or decreasing the current flow through a defective memory cell by coupling a normal memory cell among the memory cells 120 to the first variable resistance pattern 130 of a low resistance state and coupling a defective memory cell among the memory cells 120 to the first variable resistance pattern 130 of a high resistance state. This will be described below in detail with reference to FIGS. 2A to 2C.

FIGS. 2A to 2C are cross-sectional views illustrating diverse states of the semiconductor device shown in FIG. 1A.

Referring to FIG. 2A, the memory cells 120 may all correspond to normal memory cells 120′. All of the first variable resistance patterns 130 respectively coupled to the memory cells 120 may have a low resistance state LRS.

In this case, the memory cells 120 may operate normally according to the operation voltage or operation current applied through the first conductive line 110 and the second conductive line 140. When the memory cells 120 operate, the first variable resistance pattern 130 of the low resistance state LRS may act like a kind of a conductor, so the operation of the memory cells 120 may not be interrupted. As described above, since the magnitude of the set/reset voltage or set/reset current of the first variable resistance pattern 130 is greater than the magnitude of the operation voltage or operation current of the memory cell 120, even when the memory cell 120 operates, the low resistance state LRS of the first variable resistance pattern 130 may be maintained.

Referring to FIG. 2B, at least one among the memory cells 120 may correspond to a defective memory cell 120″. For example, as illustrated, the memory cell 120 in the middle among the memory cells 120 may correspond to the defective memory cell 120″. A permanent conductive path CP may be created in the defective memory cell 120″, causing a short failure. Other memory cells among the memory cells 120, except for the defective memory cell 120″, may correspond to normal memory cells 120′. Here, all the first variable resistance patterns 130 respectively coupled to the memory cells 120 may have a low resistance state LRS.

The normal memory cell 120′ may operate normally according to the operation voltage or operation current that is applied through the first conductive line 110 and the second conductive line 140. Since the first variable resistance pattern 130 of the low resistance state LRS acts like a kind of a conductor, the operation of the normal memory cell 120′ may not be interrupted.

On the other hand, since there is a permanent conductive path

CP in the defective memory cell 120″, even though the operation voltage or operation current is applied to the defective memory cell 120″ through the first conductive line 110 and the second conductive line 140, a normal operation may not be performed in the defective memory cell 120″. Furthermore, due to the conductive path CP of the defective memory cell 120″, leakage current may occur through the defective memory cell 120″ and the first variable resistance pattern 130 of the low resistance state LRS between the first conductive line 110 and the second conductive line 140. Therefore, as illustrated in FIG. 2C below, the first variable resistance pattern 130 that is coupled to the defective memory cell 120″ may need to have a high resistance state.

Referring to FIG. 2C, at least one among the memory cells 120, for example, the memory cell 120 in the middle, may correspond to the defective memory cell 120″ having a permanent conductive path CP. Other memory cells among the memory cells 120, except for the defective memory cell 120″, may correspond to normal memory cells 120′. The first variable resistance pattern 130 that is coupled to the defective memory cell 120″ may be in a high resistance state HRS, and the first variable resistance pattern 130 that is coupled to the normal memory cell 120′ may be in a low resistance state LRS.

The normal memory cell 120′ may operate normally according to the operation voltage or operation current applied through the first conductive line 110 and the second conductive line 140. Since the first variable resistance pattern 130 of the low resistance state LRS acts like a kind of a conductor, the operation of the normal memory cell 120′ may not be interrupted.

On the other hand, application of the operation voltage or operation current to the defective memory cell 120″ may be prevented. Since the first variable resistance pattern 130 of the high resistance state HRS acts like a kind of an insulator, it may substantially block the electrical connection between the defective memory cell 120″ and the second conductive line 140. Since the defective memory cell 120″ is a memory cell that cannot operate normally, it is not actually used as a memory cell, and leakage current through the defective memory cell 120″ may be blocked and/or decreased by using the first variable resistance pattern 130 of the high resistance state HRS.

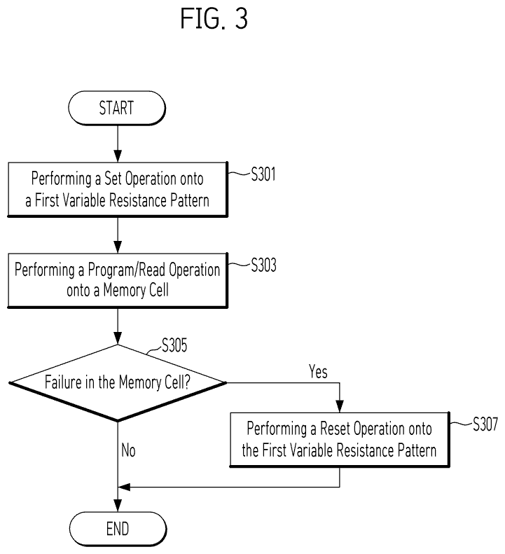

FIG. 3 is a flowchart describing a method for operating a semiconductor device in accordance with an embodiment of the present disclosure.

First, in step S301, before performing the operation of the memory cell 120, a set operation of changing the resistance states of all the first variable resistance patterns 130 into a low resistance state may be performed. The set operation may be performed when at least one among the first variable resistance patterns 130 is in a high resistance state before the operation of the memory cell 120. When all of the first variable resistance patterns 130 are in a low resistance state, the step S301 may be omitted. In other words, the step S301 may be performed selectively.

Subsequently, diverse operations, such as a program operation and a read operation, may be performed onto the memory cell 120 in step S303. Here, since the first variable resistance patterns 130 are all in a low resistance state, the operation of the memory cell 120 may not be interrupted. Since the operation voltage or operation current of the memory cell 120 is smaller than the set/reset voltage or set/reset current of the first variable resistance pattern 130, the low resistance state of the first variable resistance pattern 130 may be maintained in the step S303.

Subsequently, in step S305, a verification operation of determining whether or not there is a memory cell 120 in which a defect such as a short failure has occurred in the step S303 may be performed. Whether a short failure has occurred or not in the memory cell 120 may be determined by comparing the current flowing through the memory cell 120 with a predetermined reference current. The voltage or current applied to the memory cell 120 during the verification operation may be the same or similar to the voltage or current applied during the read operation. Accordingly, the resistance state of the first variable resistance pattern 130 may be maintained even during the verification operation. The verification operation may be performed in a section that does not overlap with a program operation and/or a read operation of the memory cell 120. For example, as illustrated, it may be performed after a program/read operation of the memory cell 120.

When it is determined that a short failure has occurred in the memory cell 120, for example, when the current flowing through the memory cell 120 is greater than the predetermined reference current, a reset operation of changing the low resistance state of the first variable resistance pattern 130 into a high resistance state may be performed in step S307. This operation may be performed only on the first variable resistance pattern 130 that is coupled to the memory cell 120 in which a short failure has occurred. In other words, a reset voltage or reset current may be applied to the first variable resistance pattern 130 that is coupled to the memory cell 120 in which a short failure has occurred through the first and second conductive lines 110 and 140 that are coupled to the memory cell 120 in which the short failure has occurred. The low-resistance state may be maintained by preventing a reset operation on the first variable resistance pattern 130 that is coupled to the normal memory cell 120. To this end, the first and second conductive lines 110 and 140 coupled to the normal memory cell 120 may be in a floating state, or a ground voltage may be applied to them.

Conversely, when it is determined that a short failure has not occurred in the memory cell 120, for example, when the current flowing through the memory cell 120 is smaller than the predetermined reference current, it does not have to perform a reset operation and the like, and the process may be terminated.

The above-described steps S305 and S307 may be repeatedly performed at predetermined intervals. For example, the steps S305 and S307 may be performed whenever a program operation and/or a read operation of the memory cell 120 is performed a predetermined number of times. Also, for example, the steps S305 and S307 may be performed whenever a predetermined time passes.

According to the embodiment of the present disclosure, the semiconductor device and the operation method thereof may have improved operation characteristics by preventing defects, such as leakage current.

While the present disclosure has been described with respect to the specific embodiments, it will be apparent to those skilled in the art that various changes and modifications may be made without departing from the spirit and scope of the disclosure as defined in the following claims.

What is claimed is:

1. A semiconductor device, comprising:
a plurality of first conductive lines extending in a first direction;
a plurality of second conductive lines disposed to be spaced apart from the plurality of first conductive lines in a third direction and extending in a second direction intersecting with the first direction;
a plurality of memory cells overlapping with intersection areas of the plurality of first conductive lines and the plurality of second conductive lines; and
a plurality of first variable resistance patterns that are respectively coupled in series to the plurality of memory cells, one first variable resistance pattern per memory cell, so that each first variable resistance pattern and a corresponding memory cell are connected between a corresponding first conductive line of the plurality of first conductive lines and a corresponding second conductive line of the plurality of second conductive lines.

2. The semiconductor device of claim 1, wherein a first variable resistance pattern amongst of the plurality of first variable resistance patterns, which is coupled in series to a defective memory cell with a short failure among the plurality of memory cells, has a high resistance state among different resistance states of the first variable resistance pattern.

3. The semiconductor device of claim 1, wherein a first variable resistance pattern amongst of the plurality of first variable resistance patterns, which is coupled in series to a normal memory cell without a short failure among the plurality of memory cells, has a low resistance state among different resistance states of the first variable resistance pattern of the first variable resistance pattern.

4. The semiconductor device of claim 1, wherein a magnitude of a voltage or a current that is required to change a resistance state of each first variable resistance pattern is greater than a magnitude of an operation voltage or an operation current that is required during a program operation or a read operation of a memory cell of the plurality of memory cells.

5. The semiconductor device of claim 1, wherein during a program operation or a read operation of a memory cell of the plurality of memory cells, a resistance state of the first variable resistance pattern is maintained without a change.

6. The semiconductor device of claim 1, wherein the first variable resistance pattern includes a phase change material.

7. The semiconductor device of claim 6, wherein a memory cell of the plurality of memory cells includes a magnetic tunnel junction structure.

8. The semiconductor device of claim 1, wherein a memory cell of the plurality of memory cells further includes a second variable resistance pattern that exhibits different resistance states for storing data for the memory cell.

9. The semiconductor device of claim 8, wherein a magnitude of a voltage or a current that is required to change a resistance state of the first variable resistance pattern is greater than a magnitude of a voltage or a current that is required to change a resistance state of the second variable resistance pattern.

10. The semiconductor device of claim 2, wherein the defective memory cell includes a permanent conductive path that allows a current to pass through the defective memory cell.

11. The semiconductor device of claim 3, wherein the normal memory cell is electrically connected to one of the plurality of first conductive lines or one of the plurality of second conductive lines by the first variable resistance pattern with the low resistance state.

12. The semiconductor device of claim 2, wherein the defective memory cell is electrically disconnected from a first conductive line or a second conductive line by the first variable resistance pattern with the high resistance state.

13. A method for operating a semiconductor device,
wherein the semiconductor device includes:
a plurality of first conductive lines extending in a first direction;
a plurality of second conductive lines disposed to be spaced apart from the plurality of first conductive lines in a third direction and extending in a second direction intersecting with the first direction;
a plurality of memory cells overlapping with intersection areas of the plurality of first conductive lines and the plurality of second conductive lines; and
a plurality of first variable resistance patterns formed to be connected in series with the plurality of memory cells, respectively, one first variable resistance pattern per memory cell, so that each first variable resistance pattern and a corresponding memory cell are connected between a corresponding first conductive line of the plurality of first conductive lines and a corresponding second conductive line of the plurality of second conductive lines,
wherein the method comprises:
determining whether or not a defective memory cell with a short failure exists among the plurality of memory cells; and
in response to the determining that the defective memory cell exists, performing a reset operation to allow a first variable resistance pattern that is coupled to the defective memory cell to exhibit a high resistance state to block an electrical connection to the defective memory cell.

14. The method of claim 13, wherein the determining and the performing are performed at a different timing from when a program operation or a read operation of a memory cell of the plurality of memory cells is performed.

15. The method of claim 14, wherein during the program operation or the read operation of the memory cell, a resistance state of the first variable resistance pattern is maintained without a change.

16. The method of claim 14, wherein a magnitude of a reset voltage or a reset current that is required during the reset operation is greater than a magnitude of an operation voltage or an operation current that is required during the program operation or the read operation.

17. The method of claim 14, further comprising:
before the performing of the program operation or the read operation,
performing a set operation to allow the first variable resistance pattern that is coupled to each of the plurality of memory cells to exhibit a low resistance state.

18. The method of claim 17, wherein a magnitude of a set voltage or a set current that is required during the set operation is greater than a magnitude of an operation voltage or an operation current that is required during the program operation or the read operation.

19. The method of claim 13, wherein the determining whether or not a defective memory cell exists among the plurality of memory cells includes:
comparing a current flowing through each of the plurality of memory cells with a reference current; and
determining a memory cell through which a current greater than the reference current flows as the defective memory cell.

20. The method of claim 19, wherein a memory cell through which a current smaller than the reference current flows is determined as a normal memory cell.
